(19) United States
(12) Patent Application Publication
(10) Pub. No.: US 2024/0347643 A1
(43) Pub. Date: Oct. 17, 2024

(54) ANTI-AMBIPOLAR TRANSISTOR HAVING VERTICAL STRUCTURE AND METHOD OF MANUFACTURING THE SAME

(71) Applicant: POSTECH RESEARCH AND BUSINESS DEVELOPMENT FOUNDATION, Pohang-si (KR)

(72) Inventors: Byoung Hun LEE, Pohang-si (KR); Yongsu LEE, Pohang-si (KR); Hae-Won LEE, Pohang-si (KR)

(73) Assignee: POSTECH RESEARCH AND BUSINESS DEVELOPMENT FOUNDATION, Pohang-si (KR)

(21) Appl. No.: 18/632,104

(22) Filed: Apr. 10, 2024

(30) Foreign Application Priority Data
Apr. 17, 2023 (KR) 10-2023-0049947

(51) Int. Cl. H01L 29/786; H01L 29/66

(52) U.S. Cl. CPC H01L 29/78642; H01L 29/66742

(57) ABSTRACT

An anti-ambipolar transistor in which a turn-on operation is performed at a specific gate voltage and a method of manufacturing the same are disclosed. A vertically stacked structure including a first semiconductor layer and a second semiconductor layer, which are disposed perpendicular to the surface of a substrate, is formed, and then a gate dielectric layer and a gate electrode, which completely surround the side of the vertically stacked structure, are formed. Through the vertical structure, an electric field is generated in a direction parallel to the substrate, and a drain-source current is applied in a direction perpendicular to the surface of the substrate. This ensures the integration of the transistor and efficient operation of the transistor.

### BACKGROUND OF THE INVENTION

### 1. Field of the Invention

The present invention relates to an anti-ambipolar transistor, and more specifically, to an anti-ambipolar transistor having a vertical structure and a method of manufacturing the anti-ambipolar transistor having a vertical structure.

### 2. Description of the Related Art

Anti-ambipolar transistors have the characteristic of turning on a channel at a specific gate voltage. This occurs when a heterojunction is used as a channel layer. Heterojunction refers to a junction in which the base materials constituting an n-type semiconductor and a p-type semiconductor are different from each other. Heterojunction has an inherent asymmetry, and a junction between an n-type semiconductor and a p-type semiconductor, which are asymmetrical to each other, can exhibit anti-ambipolar characteristics. In particular, an anti-ambipolar transistor having a high drain-source current I_{ds} at a specific gate voltage can be understood as a combination of the characteristics of monotonic switch devices.

FIG. 1 provides a cross-sectional view and characteristic graphs showing monotonic switch device of a prior art.

Referring to (a) of FIG. 1, a gate electrode 110 and a gate dielectric layer 120 are formed on a substrate 100, and a channel layer 130 is formed on the gate dielectric layer 120. The channel layer 130 is either an n-type semiconductor layer or a p-type semiconductor layer, and a source electrode 140 and a drain electrode 150 are disposed on both sides of the channel layer 130.

Referring to (b) of FIG. 1, in the case where the channel layer 130 is composed of only an n-type semiconductor layer and the gate voltage V_{g} has value above a certain level, the transistor is turned on. This results from the fact that the charge carrier of the channel layer 130 is an electron.

Moreover, in (c) of FIG. 1, the I_{d}-V_{g} characteristic where the channel layer 130 is composed of only a p-type semiconductor is illustrated. If the gate voltage V_{g} is below a certain level, the transistor is turned on, and a high drain-source current I_{d} flows. This results from the fact that the charge carrier of the channel layer 130 is a hole.

Therefore, the monotonic switch device exhibits the characteristic of a significant increase or decrease in drain current la depending on a specific gate voltage V_{g}.

FIG. 2 provides a cross-sectional view and a characteristic graph showing anti-ambipolar transistor of prior art.

Referring to (a) of FIG. 2, the arrangement of the substrate 100, gate electrode 110, gate dielectric layer 120, source electrode 140, and drain electrode 150 is the same as that of FIG. 1. However, the composition of the channel layer 130 is different from that of FIG. 1. The channel layer 130 is composed of a junction of an n-type semiconductor layer 131 and a p-type semiconductor layer 133. The electrons of the n-type semiconductor layer 131 and the holes of the p-type semiconductor layer 133 generate a drain current I_{d} across the junction at a specific gate voltage. Therefore, as shown in (b) of FIG. 2, the anti-ambipolar transistor is turned on at a specific gate voltage V_{g} and exhibits a high drain-source current I_{ds}.

The above-described structure of FIG. 2 is an application of the typical transistor structure, which is also referred to as a planar structure. In other words, a flat gate dielectric layer is formed along the surface of the substrate, and a channel layer is formed on the gate dielectric layer. Furthermore, a source electrode and a drain electrode are formed in the peripheral region of the channel layer.

The planar structure offers advantages such as simplified manufacturing process and ease of measuring the physical properties of the transistor. Particularly, forming the source and drain electrodes on the insulating gate dielectric layer facilitates the electrical contact process on their surfaces.

However, the planar structure poses an obstacle to the integration of the transistor. The n-type semiconductor layer and the p-type semiconductor layer need to be widely distributed on the substrate, and the source electrode and drain electrode also need to be electrically connected to their respective semiconductor layers, while forming lateral contacts. In other words, the conventional planar structure acts as an obstacle to the high integration of the anti-ambipolar transistor.

### SUMMARY OF THE INVENTION

The present invention has been made in an effort to solve the above-described problems associated with prior art, and a first object of the present invention is to provide an anti-ambipolar transistor having a vertical structure.

A second object of the present invention is to provide a method of manufacturing an anti-ambipolar transistor to achieve the above-mentioned first object.

To achieve the above-mentioned first object, the present invention provides an anti-ambipolar transistor comprising: a vertically stacked structure formed vertically on the surface of a substrate; a gate dielectric layer formed along the side of the vertically stacked structure; and a gate electrode formed to surround the side of the gate dielectric layer, wherein the vertically stacked structure comprises a first semiconductor layer formed on the substrate and a second semiconductor layer formed on the first semiconductor layer, wherein the first semiconductor layer and the second semiconductor layer form a pn junction, and an electric field due to a gate voltage applied through the gate electrode is applied in a direction parallel to the surface of the substrate, and wherein the vertically stacked structure generates a current in a direction perpendicular to the surface of the substrate.

The above-mentioned first object of the present invention is also achieved by providing an anti-ambipolar transistor comprising: a vertically stacked structure comprising a source electrode formed on the surface of a substrate, a first semiconductor layer formed on the source electrode, a second semiconductor layer formed on the first semiconductor layer, and a drain electrode formed on the second semiconductor layer; a gate dielectric layer formed along the side of the vertically stacked structure; and a gate electrode formed to surround the side of the gate dielectric layer, wherein the source electrode, the first semiconductor layer, the second semiconductor layer, and the drain electrode have the same shape, and the first semiconductor layer and the second semiconductor layer have complementary conductivity types, wherein an electric field due to a gate voltage applied through the gate electrode is applied in a direction parallel to the surface of the substrate, and wherein at a threshold voltage that is a specific gate voltage, the first semiconductor layer and the second semiconductor layer are turned on, causing the drain-source current to flow in a direction perpendicular to the surface of the substrate.

To achieve the above-mentioned second object, the present invention provides a method of manufacturing an anti-ambipolar transistor comprising the steps of: forming a vertically stacked structure comprising a source electrode, a first semiconductor layer, a second semiconductor layer, and a drain electrode, which have the same profile; forming a gate dielectric layer on the top and side of the vertically stacked structure and on a peripheral region other than the vertically stacked structure; and forming a gate electrode on the gate dielectric layer formed on the side of the vertically stacked structure and on the gate dielectric layer formed on a portion of the peripheral region, wherein the gate electrode exposes a portion of the gate dielectric layer formed on the upper surface of the vertically stacked structure.

According to the present invention as described above, when a gate voltage V_{g} is applied through the gate electrode, the electric field is applied in a direction parallel to the surface of the substrate. Since the gate electrode is formed to surround the vertically stacked structure through the gate dielectric layer, the electric field is applied in a direction parallel to the junction interface between the first semiconductor layer and the second semiconductor layer by the applied gate voltage. Moreover, the electric field due to the gate voltage is applied across the entire side of both the first and second semiconductor layers having a pn junction diode structure. In other words, the electric field applied around a pn junction diode, facilitating the control of the operation of the pn junction diode.

The behavior of the first semiconductor layer and the second semiconductor layer due to a specific electric field will be described below. For the sake of explanation, it is assumed that the first semiconductor layer is an n-type, and the second semiconductor layer is a p-type. When a specific electric field is applied around the junction, electrons in the first semiconductor layer migrate across the junction toward the drain electrode, and holes in the second semiconductor layer migrate across the junction toward the source electrode. Particularly, in the present invention, the gate electrode forms a structure surrounding the two semiconductor layers, facilitating the control of the drain-source current Ids.

Furthermore, the first semiconductor layer and the second semiconductor layer are vertically stacked. When forming an anti-ambipolar transistor with a structure shown in FIGS. 1 and 2, there are limitations in reducing the footprint of the transistor. In particular, in order to reduce the footprint, a method of reducing the channel length is conceivable, however, when the length of the two semiconductor layers is reduced to several nanometers, it becomes difficult to form the pn junction.

However, in the vertical structure of the present invention as described above, the first semiconductor layer and the second semiconductor layer are stacked cumulatively, and with a simple patterning process, the formation of the channel layer can be achieved, enabling the integration of device.

### BRIEF DESCRIPTION OF THE DRAWINGS

FIG. 1 provides a cross-sectional view and characteristic graphs showing a prior art monotonic switch device.

FIG. 2 provides a cross-sectional view and a characteristic graph showing a prior art anti-ambipolar transistor.

FIG. 3 is a cross-sectional view of an anti-ambipolar transistor according to a preferred embodiment of the present invention.

FIG. 4 is a cross-sectional view showing a modified structure of the anti-ambipolar transistor of FIG. 3 according to a preferred embodiment of the present invention.

FIG. 5 is a graph illustrating the operation of the anti-ambipolar transistor with the introduction of a composite layer of FIG. 4 according to a preferred embodiment of the present invention.

FIGS. 6 to 14 are diagrams illustrating a method of manufacturing the anti-ambipolar transistor of FIG. 3 according to a preferred embodiment of the present invention.

### DETAILED DESCRIPTION OF THE INVENTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the drawings, like reference numerals have been used throughout to designate like elements.

Unless defined otherwise, all terms used herein including technical or scientific terms have the same meaning as those generally understood by those skilled in the art to which the present invention pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

Hereinafter, preferred embodiments of the present invention will be described in more detail with reference to the accompanying drawings.

### EMBODIMENTS

FIG. 3 is a cross-sectional view of an anti-ambipolar transistor according to a preferred embodiment of the present invention.

Referring to FIG. 3, an anti-ambipolar transistor may comprise a substrate 200, a vertically stacked structure 300, a gate dielectric layer 410 surrounding the side of the vertically stacked structure 300, and a gate electrode 420 formed on the gate dielectric layer 410.

The substrate 200 may have insulating or semiconducting properties. For example, the substrate 200 may be made of SiO₂ or silicon. The substrate 200 may have any material as long as it is made of a material whose physical properties do not change even during the formation process of the vertically stacked structure 300, the gate dielectric layer 410, and the gate electrode 420.

In FIG. 3, the substrate 200 may be composed of a silicon substrate 210 and a SiO₂ layer 220 formed on the silicon substrate 210.

The vertically stacked structure 300 may be formed on the substrate 200. The vertically stacked structure 300 exhibits selectivity in a turn-on operation that generates a high drain-source current I_{ds} at a specific voltage by the applied gate voltage. Therefore, during the turn-on operation, the drain-source current I_{ds} flows in a direction perpendicular to the substrate 200 in the vertically stacked structure 300.

The vertically stacked structure 300 may comprise a source electrode 310, a first semiconductor layer 320, a second semiconductor layer 330, and a drain electrode 340. The source electrode 310 and the drain electrode 340 may be formed by changing their positions. The source electrode or the drain electrode may preferably be made of a metal, including Au, Pt, Ag, Ni, Al, W or Pd.

Furthermore, the first semiconductor layer 320 and the second semiconductor layer 330 may have complementary conductivity types. If the first semiconductor layer 320 is n-type, then the second semiconductor layer 330 is preferably p-type, and if the first semiconductor layer 320 is p-type, the second semiconductor layer 330 is preferably n-type.

The n-type semiconductor layer may comprise an inorganic semiconductor, a two-dimensional semiconductor, or an organic semiconductor. The inorganic semiconductor may comprise ZnO, In₂O₃, InGaO, InZnO, IGZO or SnO₂. The two-dimensional semiconductor may comprise MoS₂, MoSe₂ or WS₂. The organic semiconductor may comprise N,N′-dioctyl-3,4,9,10-perylenedicarboximide (PTCDI-C8), poly(benzimidazobenzophenanthroline) (BBL), 1,3,4,5,7,8-hexafluorotetracyanonaphthoquinodimethane (F6-TCNNQ), copper(II) 1,2,3,4,8,9,10,11,15,16,17,18,22,23,24,25-hexadecafluoro-29H,31H-phthalocyanine (F16-CuPc), 5,5′-bis((5-perfluorohexyl)thiophen-2-yl)-2,2′-bithiophene (DFH-4T), or C60(fullerene).

The p-type semiconductor layer may comprise an inorganic semiconductor, a two-dimensional semiconductor, or an organic semiconductor. The inorganic semiconductor having a p-type conductivity may comprise SnO, Cu₂O, Fe₂O₃, or Te. The two-dimensional semiconductor having a p-type conductivity may comprise MoTe₂, WSe₂, or WTe₂. The organic semiconductor having a p-type conductivity may comprise dinaphthothienothiophene (DNTT), pentacene, tetracene, oligo thiophene, polythiophene, metal phthalocyanine, or polyphenylene.

For example, the n-type semiconductor layer may comprise ZnO, and the p-type semiconductor layer may comprise dinaphthothienothiophene (DNTT). ZnO exhibits intrinsic n-type semiconductor characteristics due to defects caused by oxygen vacancies or interstitial zinc during the formation process. If necessary, nitrogen ions as donors may be additionally implanted through ion implantation to form an n-type semiconductor layer. Furthermore, when DNTT is included in the p-type semiconductor layer, an acceptor-type conductive polymer may be mixed with DNTT to form a p-type semiconductor layer.

When viewed from above, the vertically stacked structure 300 has a substantially rectangular profile, and it is desirable that the respective layers constituting the vertically stacked structure 300 have the same profile.

The gate dielectric layer 410 may be formed on the side of the vertically stacked structure 300. The gate dielectric layer 410 may be formed along the side of the vertically stacked structure 300. That is, the gate dielectric layer 410 may be formed to surround the side of the vertically stacked structure 300, which has a substantially rectangular column shape. The gate dielectric layer 410 may be made of a material that has insulating properties and can create a dielectric polarization. For example, SiO₂ may be used as a material for the gate dielectric layer 410. In addition, the gate dielectric layer 410 may comprise include Al₂O₃, HfO₂, or ZrO₂.

Furthermore, the gate dielectric layer 410 may be formed to surround the side of the vertically stacked structure 300 and extend to a portion of the substrate 200.

The gate electrode 420 may be formed on the gate dielectric layer 410. Since the gate electrode 420 is formed along the profile of the gate dielectric layer 410, the gate electrode 420 also has a shape that surrounds the side of the vertically stacked structure 300 with the gate dielectric layer 410 interposed therebetween. Additionally, the gate electrode 420 may also be formed on the gate dielectric layer 410 that extends to a portion of the substrate 200. The gate electrode 420 may be made of metal or conductive polycrystalline silicon. When the gate electrode 420 is formed of a metal, Au, Pt, Ag, Ni, Al, W, or Pd may be included in the gate electrode 420.

When the gate voltage V_{g} is applied through the gate electrode 420, an electric field is applied in a direction parallel to the surface of the substrate 200, and the first semiconductor layer 320 and the second semiconductor layer 330 are turned on at a specific intensity of the applied electric field. Consequently, the drain-source current I_{ds} can flow across the junction in a direction perpendicular to the surface of the substrate 200.

An interconnection structure is formed at the anti-ambipolar transistor shown in FIG. 3.

The interconnection structure may be provided to connect the source electrode 310, the drain electrode 340, and the gate electrode 420 to the outside, and may include a source contact 301 and first to third plugs 640 to 660. The source contact 301, the first plug 640, the second plug 650, and the third plug 660 may preferably be made of metals. For example, the source contact may comprise Au, Pt, Ag, Ni, Al, W, or Pd. Additionally, the first to third plugs may be made of the same material and may comprise Au, Pt, Ag, Ni, Al, W, or Pd.

The source contact 301 may be formed between the source electrode and the substrate. The source contact 301 may preferably be made of the same material as the source electrode 310. The source contact 301 may extend to the outside of the vertically stacked structure 300 and may be electrically connected to the outside through the first plug 640. An interlayer insulating layer 600 may be formed to cover the vertically stacked structure 300, the gate dielectric layer 410, and the gate electrode 420, and the first plug 640 may penetrate through the interlayer insulating layer 600 and the gate dielectric layer 410 to connect to the source contact 301.

The second plug 650 may penetrate through the interlayer insulating layer 600 and the gate dielectric layer 410 to connect to the vertically stacked structure 300. Specifically, the second plug 650 may be electrically connected to the upper surface of the drain electrode 340.

The third plug 660 may penetrate through the interlayer insulating layer 600 to connect to the gate electrode 420.

The vertically stacked structure of the anti-ambipolar transistor shown in FIG. 3 reduces the footprint of the transistor.

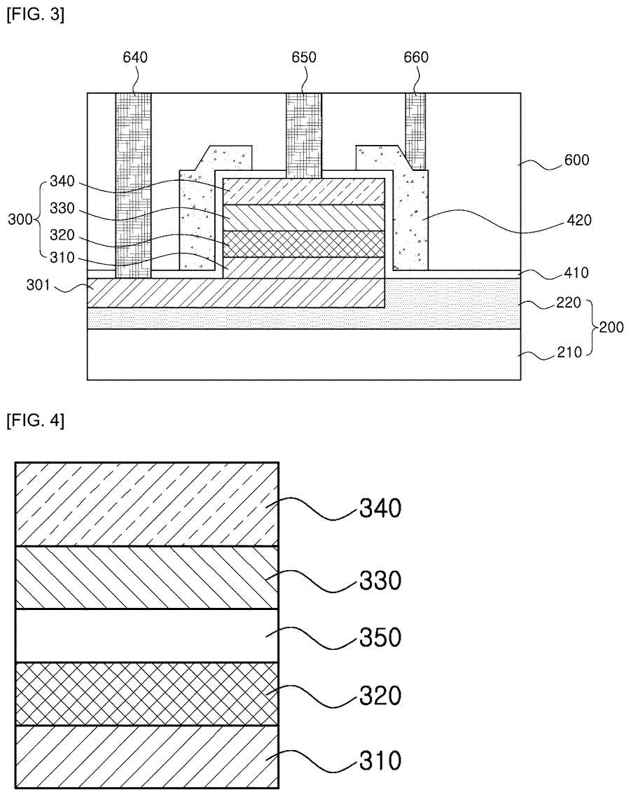

FIG. 4 is a cross-sectional view showing a modified structure of the anti-ambipolar transistor of FIG. 3 according to a preferred embodiment of the present invention.

Referring to FIG. 4, for the sake of explanation, a modified example of the vertically stacked structure is illustrated. Other structures remain the same as in FIG. 3.

Referring to FIG. 4, the vertically stacked structure may comprise a source electrode 310, a first semiconductor layer 320, a composite layer 350, a second semiconductor layer 330, and a drain electrode 340.

The source electrode 310, the drain electrode 340, the first semiconductor layer 320, the and second semiconductor layer 330 are the same as those described with respect to FIG. 3. The composite layer 350 may comprise an insulating layer and a charge injection layer. Depending on the embodiment, the configuration of the insulating layer may be omitted, and the insulating layer and the charge injection layer may be formed in reverse order to each other. In other words, the charge injection layer may be formed on the insulating layer, or the insulating layer may be formed on the charge injection layer.

The charge injection layer may comprise poly(acrylic acid) (PAA) or polyethyleneimine (PEI). When PAA is used as a material for the charge injection layer, injection of holes becomes easier, and when PEI is used as a material for the charge injection layer, injection of electrons becomes easier.

The insulating layer may comprise SiO₂, Al₂O₃, ZrO₂, or h-BN. The insulating layer may act as a barrier layer to prevent diffusion between the two semiconductor layers and limit the turn-on current. However, for the operation of the anti-ambipolar transistor, carriers need to be tunneled. For this purpose, the insulating layer may preferably have a thickness of 1 nm to 5 nm.

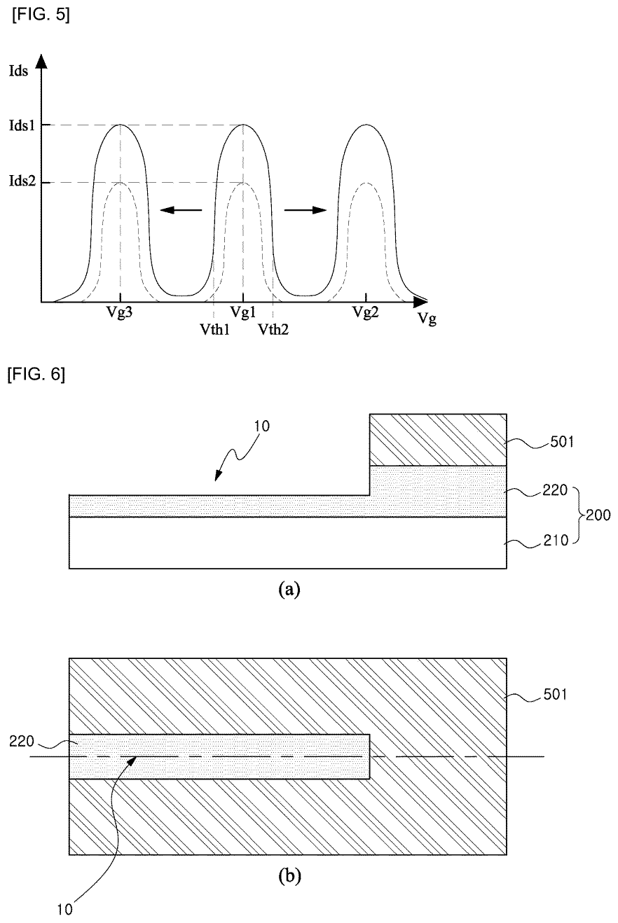

FIG. 5 is a graph illustrating the operation of the anti-ambipolar transistor with the introduction of the composite layer of FIG. 4 according to a preferred embodiment of the present invention.

First, as illustrated in FIG. 5, the characteristic graph (solid line) shows that the anti-ambipolar transistor without the composite layer 350 is turned on at a specific gate voltage, i.e., between a first threshold voltage Vₜₕ₁ and a second threshold voltage Vₜₕ₂. As a result, the anti-ambipolar transistor performs a turn-on operation when the gate voltage V_{g} is between Vₜₕ₁ and Vₜₕ₂, and at a gate voltage V_{g1}, it has the maximum drain-source current I_{ds1} depending on the drain-source voltage V_{ds}. In this embodiment, the gate voltage at which the anti-ambipolar transistor is turned on can also be represented as a threshold voltage, and the same applies hereinafter.

With the introduction of an insulating layer into the composite layer 350, a drain-source current I_{ds2} lower than I_{ds1} is observed at the same voltage V_{ds}.

Moreover, with the introduction of PEI into the composite layer 350, the gate voltage V_{g}, which generates the maximum drain-source current I_{ds} of the turned-on transistor, shifts to a high level, reaching the maximum drain-source current I_{ds} at the gate voltage V_{g2}. On the contrary, with the introduction of PAA into the composite layer, the gate voltage V_{g}, which generates the maximum drain-source current Ids, shifts to a lower level, reaching the maximum drain-source current I_{ds} at the gate voltage V_{g3}.

As described above, the introduction of the composite layer 350 allows for the control of the gate voltage V_{g}, corresponding to the threshold voltage, as well as the drain-source current I_{ds}.

FIGS. 6 to 14 are diagrams illustrating a method of manufacturing the anti-ambipolar transistor of FIG. 3 according to a preferred embodiment of the present invention.

Referring to FIG. 6, (a) represents a cross-sectional view of the manufacturing process, and (b) represents a plan view of (a) viewed from above, and the same applies hereinafter. The substrate 200 may be a silicon-on-insulator (SOI) or may comprise a SiO₂ layer 220 formed on a silicon substrate 210. As used herein, the term “substrate” refers to a substrate comprising a SiO₂ layer formed on a silicon substrate; however, it should be understood by those skilled in the art that the substrate 200 of the present invention may comprise an insulating or semiconductor material.

A photoresist may be applied to the substrate 200, and a first photoresist pattern 501 may be formed through patterning. Subsequently, the substrate 200 may be etched using the first photoresist pattern 501 as an etch mask to form a first trench 10. The first trench 10 may be recessed from the surface of the substrate 200 and exposes a portion of the SiO₂ layer 220, which is an insulating layer.

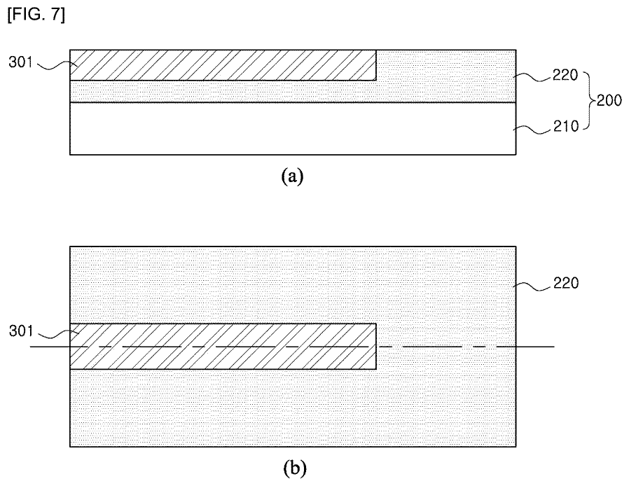

Referring to FIG. 7, a metal may be deposited on the entire surface of the structure of FIG. 6. The metal may be formed by filling the first trench and may also be formed on the first photoresist pattern.

Subsequently, a lift-off process may be performed to remove the first photoresist pattern, resulting in the removal of other metals than the metal formed in the first trench. This process allows for the formation of a source contact 301 that fills the first trench of the substrate 200. The source contact 301 may preferably be made of a metal. The material for the source contact 301 may be selected to have high adhesion and low interfacial resistance with the subsequently formed source electrode. The material for the source contact 301 may be the same as those described with respect to FIG. 3.

In FIG. 7, it is shown that the source contact 301 is formed in the recessed region from the substrate 200, however, the source contact 301 may also be formed directly on the substrate 200. Therefore, the forming process of the first trench may be omitted, and the source contact 301 may be formed in the form of wiring on the substrate.

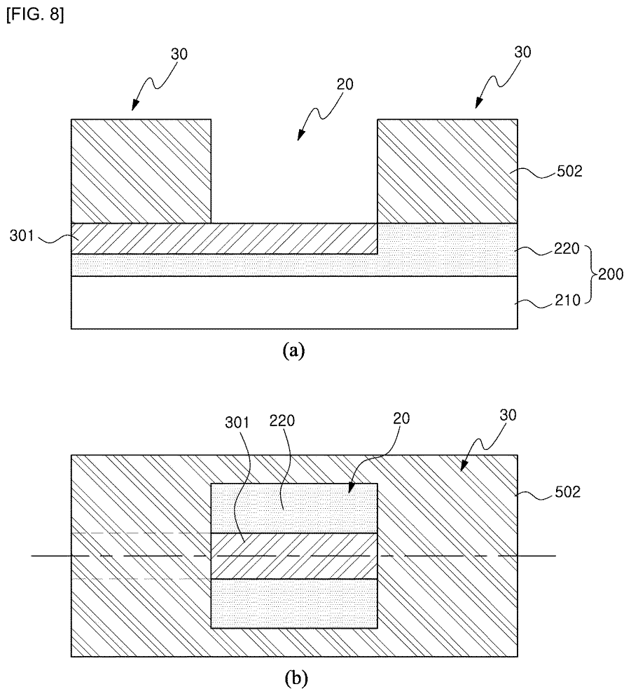

Referring to FIG. 8, a photoresist may be applied to the structure of FIG. 7, and a second photoresist pattern 502 may be formed through patterning. The second photoresist pattern 502 may open a vertically stacked region 20 and cover a peripheral region 30. The vertically stacked region 20 refers to a region where the vertically stacked structure of FIG. 3 is formed. The vertically stacked region 20 corresponds to the center of the substrate 200, and the second photoresist pattern 502 has been formed on the peripheral region 30. The source contact 301 and a portion of the substrate 200 may be exposed from the vertically stacked region 20 opened by the second photoresist pattern 502. Depending on the embodiment, only the source contact 301 may be exposed from the opened vertically stacked region 20.

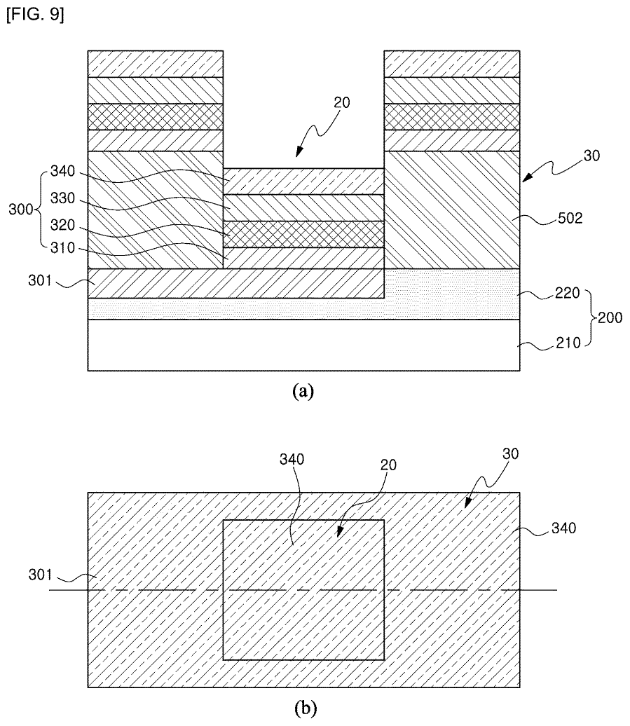

Referring to FIG. 9, a deposition process may be performed on the structure of FIG. 8 so that the source electrode 310, the first semiconductor layer 320, the second semiconductor layer 330, and the drain electrode 340 may be sequentially stacked. The layers formed within the vertically stacked region 20 may be formed with a step difference with respect to the layers formed in the peripheral region 30 other than the vertically stacked region 20. The height of the layers formed in the vertically stacked region 20 may preferably be lower than that of the second photoresist pattern 502 that defines the vertically stacked region 20.

When the vertically stacked structure 300 shown in FIG. 4 is formed, the composite layer 350, the second semiconductor layer 330, and the drain electrode 340 may be sequentially formed on the first semiconductor layer 320.

Depending on the embodiment, the formation of the source electrode 310 may be omitted. If the formation of the source electrode 310 is omitted, the source contact 301 formed at the bottom may act as the source electrode.

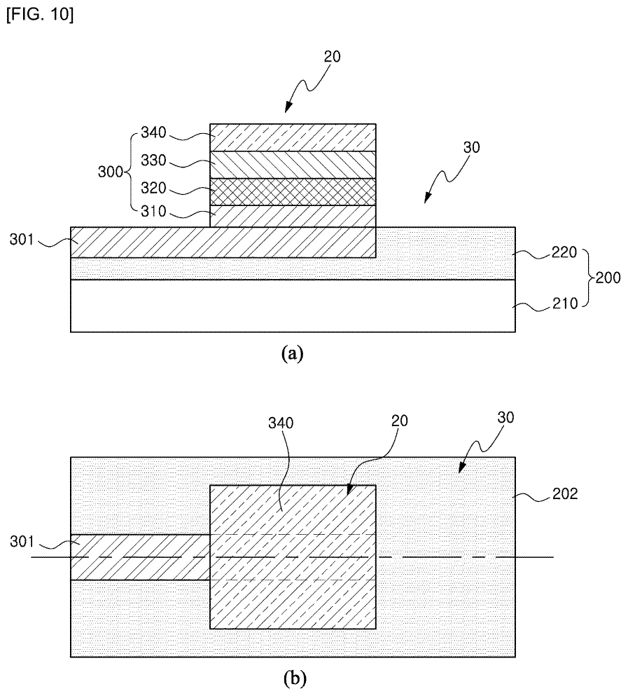

Referring to FIG. 10, a lift-off process may be performed to remove the second photoresist pattern formed in the structure of FIG. 8. As a result, the layers formed on the peripheral region 30 may be removed along with the second photoresist pattern. The vertically stacked structure 300 may be formed through the lift-off process. Particularly, the source electrode 310 may be connected to the source contact 301.

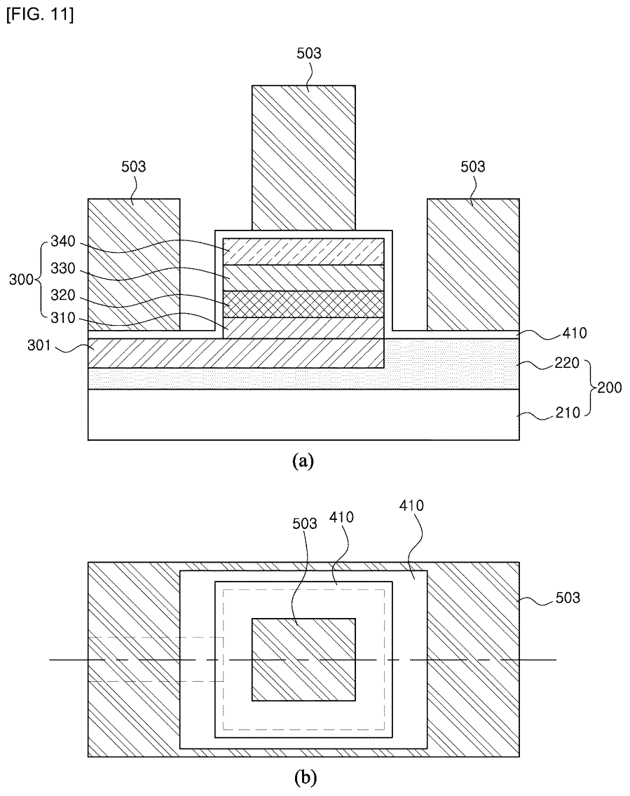

Referring to FIG. 11, the gate dielectric layer 410 may be conformally deposited to the entire surface of the structure of FIG. 10. As a result, the gate dielectric layer 410 may be formed to surround the top and side of the vertically stacked structure 300 and may also be formed on the substrate 200 in the peripheral region 30.

Subsequently, a third photoresist pattern 503 may be formed on the top of the gate dielectric layer 410 through a typical photolithography process. Specifically, the third photoresist pattern 503 may open the side of the gate dielectric layer 410 and may also open the peripheral region adjacent to the vertically stacked structure 300. The height of the third photoresist pattern 503 formed on the peripheral region may preferably be higher than that of the vertically stacked structure 300. The third photoresist pattern 503 may also be formed on the gate dielectric layer 410 formed on the upper surface of the vertically stacked structure 300; however, it is desirable for the third photoresist pattern 503 to cover only a portion of the center of the vertically stacked structure 300, rather than covering the entire upper surface thereof.

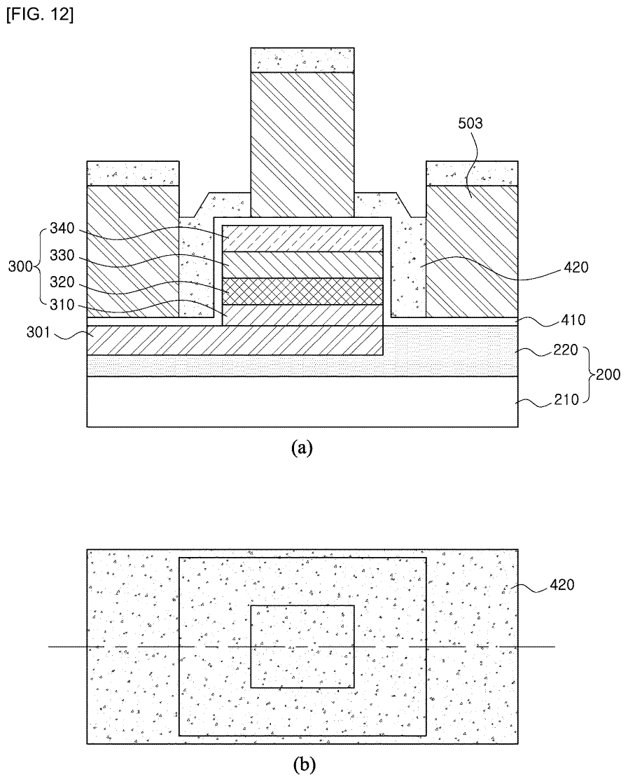

Referring to FIG. 12, the gate electrode 420 may be formed on the structure of FIG. 11 through a typical deposition process. A metal such as Au, Pt, Ag, Ni, W, or Pd may be conformally deposited to form the gate electrode 420. The metal may fill the space between the third photoresist pattern 503 in the peripheral region and the gate dielectric layer 410 formed on the side of the vertically stacked structure 300, forming the gate electrode 420. However, the gate electrode 420 may be formed partially on the upper surface of the vertically stacked structure 300.

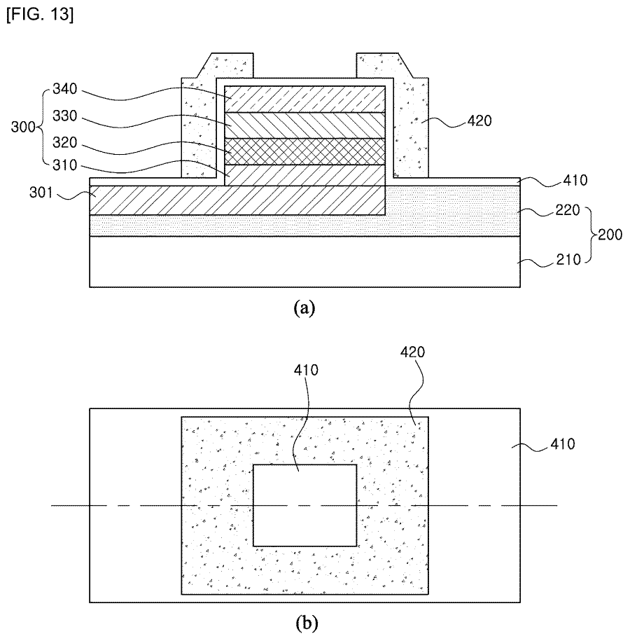

Referring to FIG. 13, a lift-off process may be performed to remove the third photoresist pattern. Through this lift-off process, the third photoresist pattern formed on the peripheral region and on the top of the vertically stacked structure 300 may be removed, along with the metal deposited on the removed third photoresist pattern. This allows for the formed gate electrode 420 to be exposed. The formed gate electrode 420 may preferably have a shape that extends partially over the upper surface of the vertically stacked structure 300.

The formed gate electrode 420 may have a shape that completely surrounds the side of the gate dielectric layer 410. The gate dielectric layer 410 may completely surround the side of the vertically stacked structure 300 and cover the upper surface of the vertically stacked structure 300.

This enables the fabrication of an anti-ambipolar transistor with a vertical structure.

Hereinafter, the interconnection process of the anti-ambipolar transistor of FIG. 13 will be described in detail.

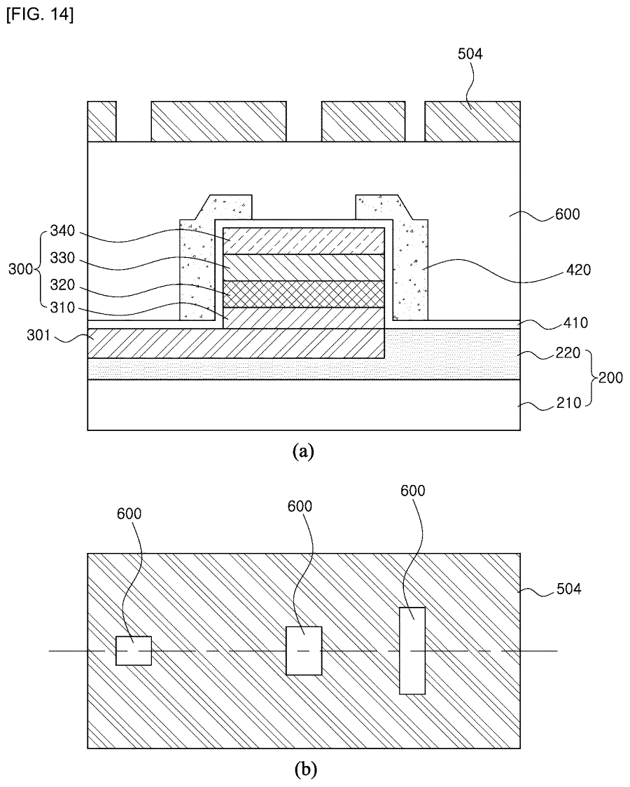

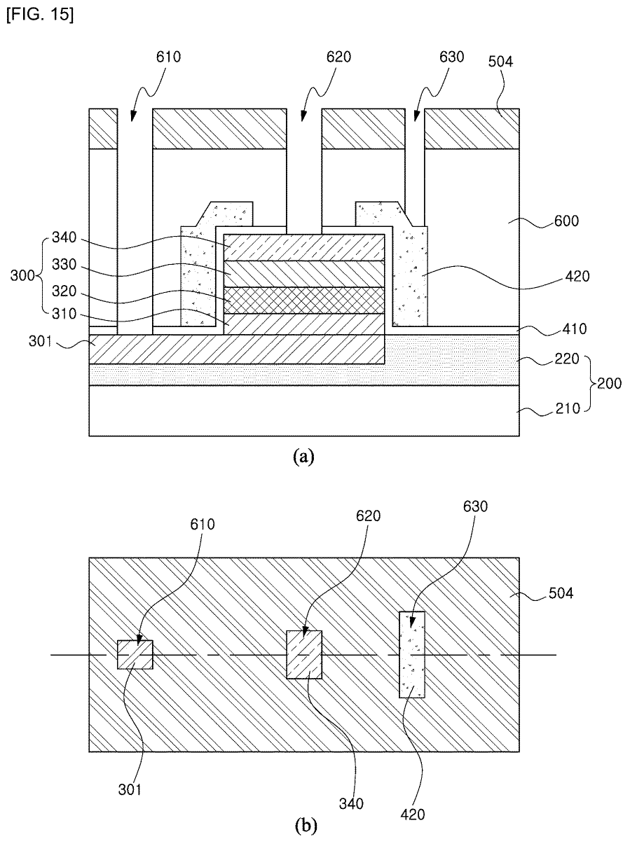

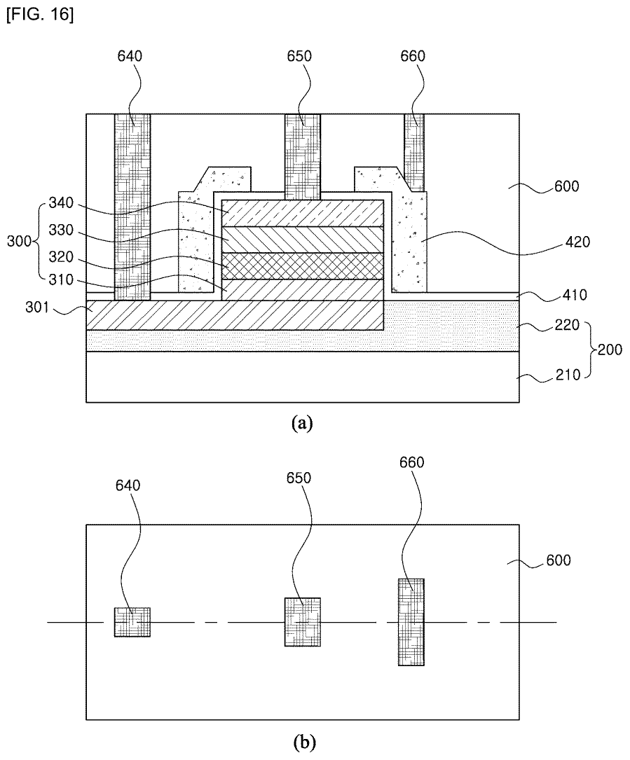

Referring to FIG. 14, an interlayer insulating layer 600 may be formed on the structure of FIG. 13 through a deposition process. The interlayer insulating layer 600 may preferably be formed to completely cover the structure of FIG. 13 and to have a flat profile on its upper surface. For this purpose, insulating material used as an interlayer insulating layer in a typical semiconductor manufacturing process may be adopt.

Subsequently, a fourth photoresist pattern 504 may be formed on the interlayer insulating layer 600. The formed fourth photoresist pattern 504 may expose a portion of the surface of the interlayer insulating layer 600 formed on the vertically stacked structure 300. Specifically, the fourth photoresist pattern 504 may open the interlayer insulating layer 600 formed on the top of the vertically stacked structure 300 and may also open the interlayer insulating layer 600 formed on the gate electrode 420 surrounding the vertically stacked structure 300. Moreover, the interlayer insulating layer 600 formed on the source contact 301 formed in the peripheral region may also be opened.

Referring to FIG. 15, an etching process may be performed using the fourth photoresist pattern 504 as an etch mask. The etching may preferably be anisotropic dry etching, and CF₄ plasma may be used as an etchant. This process results in the etching of oxides, while metals resist etching. Consequently, first to third via-holes 610 to 630 may be formed through etching. The first via-hole 610 may penetrate through the interlayer insulating layer 600 and the gate dielectric layer 410, exposing a portion of the source contact 301. Through the second via-hole 620, a portion of the gate dielectric layer 410 on the top of the vertically stacked structure 300 may be removed, exposing a portion of the drain electrode 340. The third via-hole 630 may penetrate through the interlayer insulating layer 600 on the top of the gate electrode 420, exposing the upper surface of the gate electrode 420.

Referring to FIG. 16, a metal deposition process may be performed on the structure of FIG. 15. The first to third via-holes may be filled with metal, forming plugs. The first plug 640 may fill the first via-hole to connect to the lower source contact 301 by filling. The second plug 650 may fill the second via-hole to electrically connect to the drain electrode 340. Similarly, the third plug 660 may fill the third via-hole to electrically connect to the gate electrode 420.

This allows the source electrode 310, the drain electrode 340, and the gate electrode 420 to be electrically connected to the outside of the anti-ambipolar transistor.

In this embodiment as described above, when the gate voltage V_{g} is applied through the gate electrode, the electric field is applied in a direction parallel to the surface of the substrate. Since the gate electrode is formed to surround the vertically stacked structure through the gate dielectric layer, the electric field is applied in a direction parallel to the junction interface between the first semiconductor layer and the second semiconductor layer by the applied gate voltage. Moreover, the electric field due to the gate voltage is applied across the entire side of both the first and second semiconductor layers having a pn junction diode structure. In other words, the electric field is applied around the pn junction diode, facilitating the control of the operation of the pn junction diode.

The behavior of the first semiconductor layer and the second semiconductor layer due to a specific electric field will be described below. For the sake of explanation, it is assumed that the first semiconductor layer is an n-type, and the second semiconductor layer is a p-type. When an electric field is applied around the junction, electrons in the first semiconductor layer migrate across the junction toward the drain electrode, and holes in the second semiconductor layer migrate across the junction toward the source electrode. Particularly, in the present invention, the gate electrode forms a structure surrounding the two semiconductor layers, facilitating the control of the drain-source current I_{ds}.

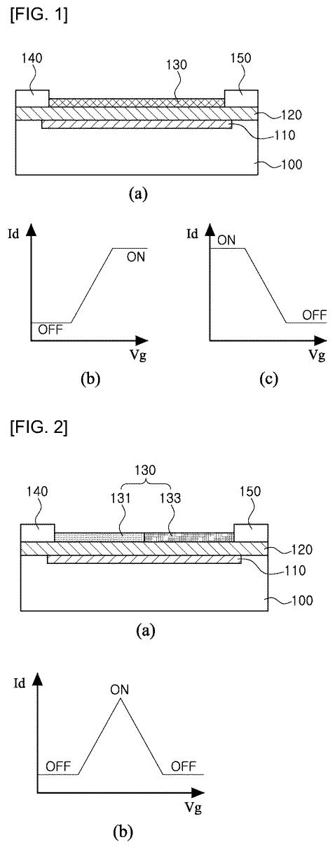

Furthermore, the first semiconductor layer and the second semiconductor layer are vertically stacked. When forming an anti-ambipolar transistor with a structure shown in FIGS. 1 and 2, there are limitations in reducing the footprint of the transistor. In particular, in order to reduce the footprint, a method of reducing the channel length is conceivable; however, when the length of the two semiconductor layers is reduced to several nanometers, it becomes difficult to form the pn junction.

However, in the vertical structure of the present invention as described above, the first semiconductor layer and the second semiconductor layer are stacked cumulatively, and with a simple patterning process, the formation of the channel layer can be achieved, enabling the integration of the device.

While the invention has been shown and described with reference to certain preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

What is claimed is:

1. An anti-ambipolar transistor comprising:
a vertically stacked structure formed vertically on the surface of a substrate;
a gate dielectric layer formed along the side of the vertically stacked structure; and
a gate electrode formed to surround the side of the gate dielectric layer,
wherein the vertically stacked structure comprises a first semiconductor layer formed on the substrate and a second semiconductor layer formed on the first semiconductor layer,
wherein the first semiconductor layer and the second semiconductor layer form a pn junction, and an electric field due to a gate voltage applied through the gate electrode is applied in a direction parallel to the surface of the substrate, and
wherein the vertically stacked structure generates a current in a direction perpendicular to the surface of the substrate.

2. The anti-ambipolar transistor of claim 1, wherein the vertically stacked structure comprising:
a source electrode formed on the substrate;
a first semiconductor layer formed on the source electrode;
a second semiconductor layer formed on the first semiconductor layer; and
a drain electrode formed on the second semiconductor layer, and
wherein the anti-ambipolar transistor is turned on at a specific gate voltage of the gate electrode.

3. The anti-ambipolar transistor of claim 2, wherein the junction interface between the first semiconductor layer and the second semiconductor layer is parallel to the surface of the substrate.

4. The anti-ambipolar transistor of claim 1, wherein the gate dielectric layer is also formed to extend over the surface of the substrate, which is a peripheral region outside the vertically stacked structure.

5. The anti-ambipolar transistor of claim 4, wherein the gate electrode is formed to surround the gate dielectric layer formed in the peripheral region and on the side of the vertically stacked structure.

6. The anti-ambipolar transistor of claim 2, further comprising a source contact formed between the substrate and the vertically stacked structure and connecting to the source electrode.

7. The anti-ambipolar transistor of claim 6, further comprising:
an interlayer insulating layer that completely covers the gate dielectric layer, the gate electrode, and the vertically stacked structure;
a first plug that penetrates through the interlayer insulating layer and the gate dielectric layer in the peripheral region to connect to the source contact;
a second plug that penetrates through the interlayer insulating layer to connect to the upper surface of the drain electrode of the vertically stacked structure; and
a third plug that penetrates through the interlayer insulating layer to connect to the upper surface of the gate electrode.

8. The anti-ambipolar transistor of claim 1, wherein the vertically stacked structure comprising:
a source electrode formed on the substrate;
a first semiconductor layer formed on the source electrode;
a second semiconductor layer formed on the first semiconductor layer; and
a drain electrode formed on the second semiconductor layer, and
wherein the anti-ambipolar transistor is turned on at a specific gate voltage of the gate electrode, and the source electrode changes the gate voltage, at which the anti-ambipolar transistor is turned on, or changes the drain-source current.

9. The anti-ambipolar transistor of claim 8, wherein the composite layer comprises an insulating layer or a charge injection layer, and when the insulating layer is included in the composite layer, the drain-source current decreases.

10. The anti-ambipolar transistor of claim 9, wherein the charge injection layer comprises PAA or PEI to cause the gate voltage at which the anti-ambipolar transistor is turned on to increase or decrease.

11. An anti-ambipolar transistor comprising:
a vertically stacked structure comprising a source electrode formed on the surface of a substrate, a first semiconductor layer formed on the source electrode, a second semiconductor layer formed on the first semiconductor layer, and a drain electrode formed on the second semiconductor layer;
a gate dielectric layer formed along the side of the vertically stacked structure; and
a gate electrode formed to surround the side of the gate dielectric layer,
wherein the source electrode, the first semiconductor layer, the second semiconductor layer, and the drain electrode have the same shape, and the first semiconductor layer and the second semiconductor layer have complementary conductivity types,
wherein an electric field due to a gate voltage applied through the gate electrode is applied in a direction parallel to the surface of the substrate, and wherein at a threshold voltage that is a specific gate voltage, the first semiconductor layer and the second semiconductor layer are turned on, causing the drain-source current to flow in a direction perpendicular to the surface of the substrate.

12. The anti-ambipolar transistor of claim 11, wherein the vertically stacked structure further comprises a composite layer for changing the threshold voltage or the drain-source current between the first semiconductor layer and the second semiconductor layer.

13. The anti-ambipolar transistor of claim 12, wherein the composite layer comprises an insulating layer or a charge injection layer, the insulating layer reduces the drain-source current, and the charge injection layer comprises PAA or PEI to cause the threshold voltage to increase or decrease.

14. A method of manufacturing an anti-ambipolar transistor comprising the steps of:
forming a vertically stacked structure comprising a source electrode, a first semiconductor layer, a second semiconductor layer, and a drain electrode, which have the same profile;
forming a gate dielectric layer on the top and side of the vertically stacked structure and on a peripheral region other than the vertically stacked structure; and
forming a gate electrode on the gate dielectric layer formed on the side of the vertically stacked structure and on the gate dielectric layer formed on a portion of the peripheral region, wherein the gate electrode exposes a portion of the gate dielectric layer formed on the upper surface of the vertically stacked structure.

15. The method of manufacturing an anti-ambipolar transistor of claim 14, wherein the step of forming a vertically stacked structure comprises the steps of:
forming a first photoresist pattern on the substrate:
forming a first trench that is recessed from the surface of the substrate by etching the first photoresist pattern;
forming a source contact by filling the first trench with a metal;
forming a second photoresist pattern that opens the vertically stacked structure and covers a peripheral region on the substrate by removing the first photoresist pattern;
sequentially stacking the source contact, the first semiconductor layer, the second semiconductor layer, and the drain electrode on the substrate on which the second photoresist pattern has been formed; and
exposing the vertically stacked structure by removing the second photoresist pattern.

16. The method of manufacturing an anti-ambipolar transistor of claim 14, wherein the step of forming a gate electrode comprises the steps of:
forming a third photoresist pattern that opens the gate dielectric layer formed on the vertically stacked structure and also opens the peripheral region adjacent to the vertically stacked structure;
forming the gate electrode to surround the gate dielectric layer formed on the side of the vertically stacked structure by depositing a metal on the substrate on which the third photoresist pattern has been formed; and
exposing the gate electrode by removing the third photoresist pattern.

17. The method of manufacturing an anti-ambipolar transistor of claim 14, further comprising, after the step of forming a gate electrode, the step of a wiring process in which the source electrode, the drain electrode, and the gate electrode are electrically connected to the outside.

18. The method of manufacturing an anti-ambipolar transistor of claim 17, wherein the wiring process comprises the steps of:
applying an interlayer insulating layer on the substrate on which the gate dielectric layer and the gate electrode have been formed; and
forming a first plug, a second plug, and a third plug, which penetrate through the interlayer insulating layer,
wherein the first plug is electrically connected to the source electrode, the second plug is electrically connected to the drain electrode, and the third plug is electrically connected to the gate electrode.
